(19) United States
(12) Patent Application Publication
(10) Pub. No.: US 2002/0187616 A1
(43) Pub. Date: Dec. 12, 2002

(54) Method of eliminating leakage current in shallow trench isolation

(76) Inventors: Chung-Ching Lai, Taipei (TW); Jui-Ping Li, Ilan Hsien (TW); Tung-Ming Lai, Taipei Hsien (TW); Chien-Nan Tu, Kaohsiung (TW)

Correspondence Address: BIRCH STEWART KOLASCH & BIRCH, PO BOX 747, FALLS CHURCH, VA, 22040-0747, US

(21) Appl. No.: 09/984,444

(22) Filed: Oct. 30, 2001

(30) Foreign Application Priority Data
Jun. 8, 2001 (TW) 90113935

(51) Int. Cl. H01L 21/336; H01L 21/76

(52) U.S. Cl. 438/425; 438/424; 438/296

(57) ABSTRACT

A method of eliminating leakage current in shallow trench isolation is disclosed. After the trench is formed on the substrate, the liner oxide layer is formed in the furnace by introducing transdichloroethylene (TLC) into the furnace to round the corner of the trench. An electric filed near the rounded trench corner is decreased; thus, the leakage current produced in the corner of the shallow trench isolation is eliminated.

### BACKGROUND OF THE INVENTION

1. Field of the Invention

The present invention relates in general to a method of manufacturing a shallow trench isolation (STI). More particularly, the present invention relates to a method of rounding the corner of the trench to eliminate leakage current in the STI.

2. Description of the Related Art

An isolation region is formed in an integrated circuit for the purpose of separating neighboring device regions of a substrate and preventing carriers from penetrating the substrate to neighboring devices.

Shallow trench isolation (STI) technique is a common method of forming isolation regions. STI structures are formed by first anisotropically etching to form a trench in the substrate, and then depositing oxide in the trench to form an isolation region. Since STI structure is scaleable, it has become widely used for forming sub-micron CMOS circuits.

The conventional method for forming the STI is described here. At first, a pad oxide layer and a silicon nitride layer are formed on a silicon substrate. A photolithographic and etching process is performed to pattern the silicon nitride layer and the pad oxide layer, and to then form a trench in the substrate. A liner oxide layer is formed by thermal oxidation on the surface of the trench. CVD oxide layer is deposited and fills the trench. A chemical mechanical polish (CMP) removes the unwanted oxide layer using the silicon nitride layer as a polishing stop layer. The silicon nitride layer and the pad oxide layer are then removed. The gate oxide layer and the gate polysilicon layer will cover the substrate in the following MOS transistor formation step.

However, the corner of the trench is sharp, when the gate oxide layer and the gate polysilicon layer cross the edge of the STI, the thin oxide layer and the polysilicon layer wrap around the corner to form parasitic corner conduction, and the local electric field is too strong to lead the occurrence of sub-MOS. The curve of log I_{d}-V_{g} in the sub-threshold region makes a hump. Moreover, when the channel of the MOS shrinks, the hump phenomenon is more pronounced. Hence the threshold voltage (Vₜₕ) is reduced. Due to the focus of the electric field made the thin corner oxide layer break down, the leakage current occurs easily.

In general, the method of resolving the problems is to round the corner of the trench to reduce the electric field in the corner near the isolation edge. One way to round the corner is thermal treatment of the wafer before forming the liner oxide layer. The temperature is higher than 1100° C. At this high temperature, the silicon atoms migrate, rounding the corner. However, the high thermal treating process impacts the lifetime of the machine and costs are increased.

### SUMMARY OF THE INVENTION

The present invention provides a method for increasing the curvature radius of the corner of the trench so as to eliminate the leakage current occurred in the STI without impacting the lifetime of the machine.

A method of eliminating the leakage current for the shallow trench isolation comprises the following steps. When the trench is formed on the substrate, the wafer is set in the furnace with introduction of the oxidation gases and TLC. During formation of the liner oxide layer, the corner of the trench is rounded. Therefore, leakage current can be eliminated.

In accordance with the present invention, the content of the TLC is about 0.5˜5 wt. %. The liner oxide layer is formed by oxidizing at 900˜1150° C.

### BRIEF DESCRIPTION OF THE DRAWINGS

The present invention will become more fully understood from the detailed description given hereinbelow and the accompanying drawings, given by way of illustration only and thus not intended to be limitative of the present invention.

FIGS. 1A through 1E are schematic, cross-sectional views showing a method of fabricating a shallow trench isolation according to the present invention.

### DETAILED DESCRIPTION OF THE PREFERRED EMBODIMENT

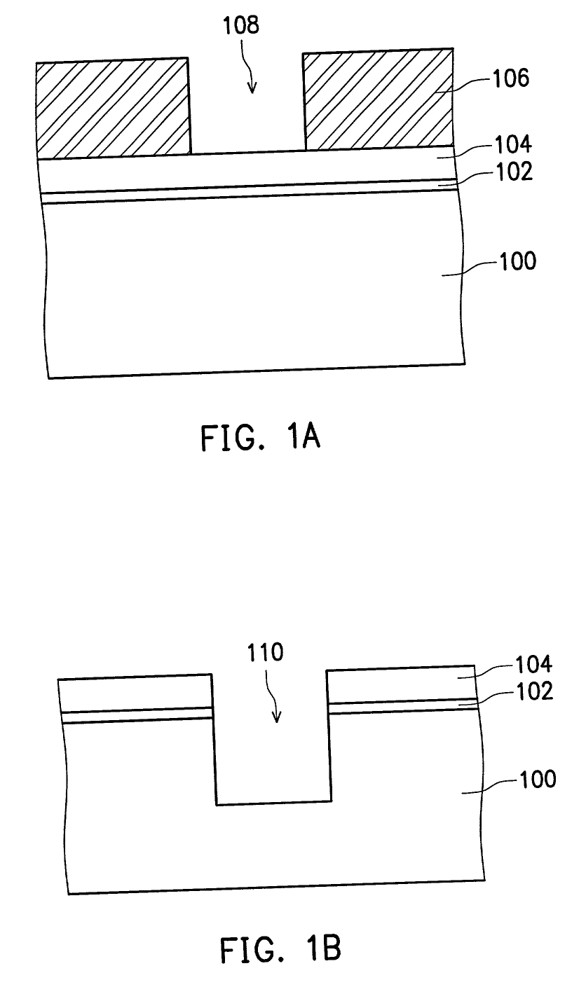

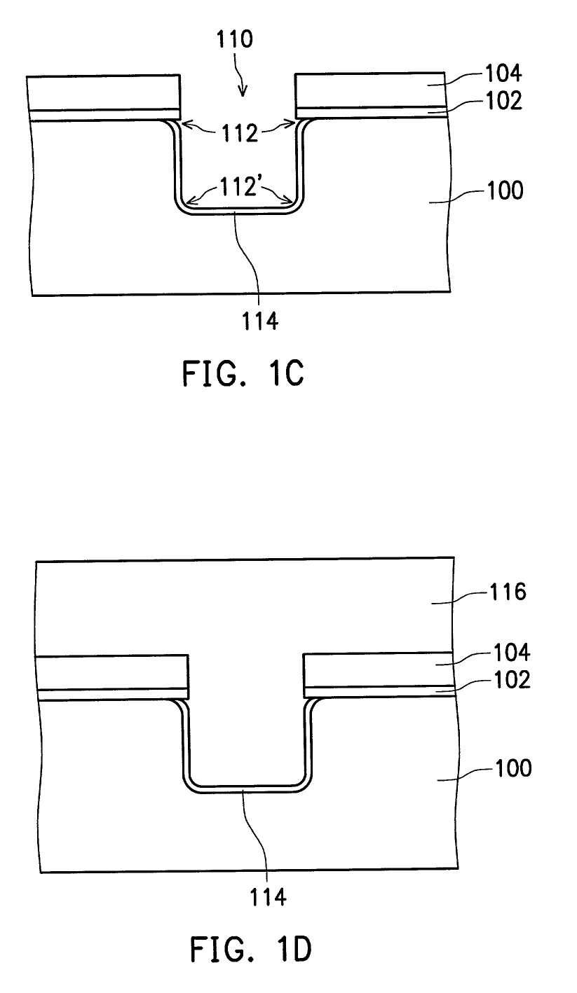

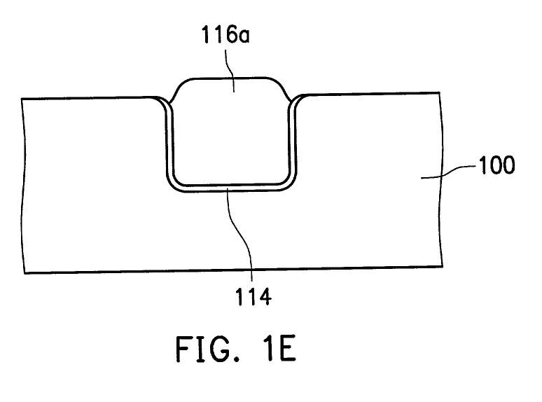

The present invention provides a method of rounding the corner of the trench to eliminate leakage current in an STI. The detailed description is given hereafter, referring to FIGS. 1A˜1E.

Referring to FIG. 1A, a substrate 100, such as silicon substrate, is provided. A pad oxide layer 102 and a mask layer 104 are sequentially formed on the substrate 100. The pad oxide layer 102 can be formed by thermal oxidation or chemical vapor deposition. The mask layer 104 can be formed by chemical vapor deposition, and the material used can be silicon nitride. A patterned photoresist layer 106 is formed on the mask layer 104 with an opening 108 therein. The opening 108 corresponds to the region of the isolation region.

Referring to FIG. 1B, etching is conducted using the patterned photoresist layer 106 as an etching mask layer. Therefore, the pattern in the patterned photoresist layer 106 is transferred to the mask layer 104, the pad oxide layer 102 and the substrate 100 by an anisotropic etching step until the substrate 100 is etched to a predetermined depth. The depth of the trench 110 formed in the substrate 100 is about 3000˜6000 Å. The patterned photoresist layer 106 is then removed by suitable etchant or dry etching.

With reference to FIG. 1C, a liner oxide layer 114 is formed on the surface of the trench 110 in the furnace and the corner 112 of the trench 110 is rounded at the same time. The method comprises introducing the oxidation gases for dry or wet oxidation and transdichloroethylene (TLC) into the furnace. The content of TLC in the processing gases is about 0.5˜5 wt. %. The processing temperature is about 900˜1150° C. The thickness of the liner oxide layer 114 is about 50˜500 Å.

If the liner oxide layer 114 grows with wet oxidation, the processing gases include hydrogen, oxygen and 0.5˜5 wt. % of TLC. If the liner oxide layer 114 grows with dry oxidation, the processing gases include oxygen and 0.5˜5 wt. % of TLC.

Because of the existence of TLC during formation of the liner oxide layer 114, the silicon atoms migrate so that the corner 112 of the trench 110 is rounded. The method for rounding the corner 112 of the trench 110 is simple. Further, due to the existence of TLC, the migration temperature of the silicon atoms is reduced, so that the silicon atoms can migrate at the processing temperature of 900˜1150° C. and the lifetime of the furnace is not impacted. Furthermore, the corner 112′ located in the bottom of the trench 110 is also rounded, and the stress produced in growing the liner oxide layer 114 is relaxed.

As shown in FIG. 1D, an insulator 116 is formed on the mask layer 104 and fills the trench 110. The insulator 116 is formed by HDP, and the material used can be silicon oxide. Then an anneal step is proceeded to densify the texture of the insulator 116.

As shown in FIG. 1E, the insulator 116 over the mask layer 104 is stripped by chemical mechanical polishing, and then the mask layer 104 and the pad oxide layer 102 are removed so as to form a STI 116a. The mask layer 104 is removed by wet etching, such as using hot phosphoric acid as an etchant. The pad oxide layer 102 is removed by wet etching, such as using hydrofluoric acid as an etchant.

During removal of the pad oxide layer 102, the insulator 116 and the liner oxide layer 114 having the same material of silicon oxide is also partially removed. However, the corner 112 of the trench 110 is rounded, the gate oxide layer (not shown) will have uniform thickness in the corner 112. The corner 112 of the trench 110 has a larger curvature radius, therefore the electric field can not focus on this area in operating the MOS.

According to the above-mentioned description, the present invention has at least the following advantages.

a. When the liner oxide layer is formed, the corner of the trench is rounded at the same time. If wet oxidation process is used, the processing gases include hydrogen, oxygen and TLC. If dry oxidation is used, the processing gases include oxygen and TLC.

b. The present invention provides the method for rounding the corner of the trench without additional processes. The method is simple. The processing temperature driving the silicon atoms' migration is lower than the traditional migration temperature of the silicon atoms. Therefore, the lifetime of the furnace is not impacted by the processing temperature.

c. The method of the present invention can not only round the corner located in the top of the trench but also round that in the bottom of the trench. The top corner has a larger curvature radius; therefore, the electric field can not focus on this area in operating the MOS. The bottom corner is thus rounded; therefore, the stress produced by trench formation is relaxed.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A method of eliminating leakage current in shallow trench isolation, comprising:
providing a substrate;
etching the substrate to form a trench therein;
performing a thermal oxidation process with transdichloroethylene (TLC) as a processing gas to form a liner oxide layer on the surface of the trench and round the corner of the trench; and
forming an insulator in the trench.

2. The method as claimed in claim 1, wherein the thermal oxidation process is dry oxidation.

3. The method as claimed in claim 1, wherein the thermal oxidation process is wet oxidation.

4. The method as claimed in claim 1, wherein the content of TLC is 0.5˜5 wt. %.

5. The method as claimed in claim 4, wherein the temperature used in the thermal oxidation process is 900˜1150° C.

6. A method of eliminating leakage current in shallow trench isolation, comprising:
providing a substrate;
forming a pad oxide layer and a mask layer on the substrate;
patterning the pad oxide layer and the mask layer to act as an etching mask;
etching the substrate to form a trench therein;
forming a liner oxide layer on the surface of the trench and rounding the corner of the trench in a furnace at the same time;
forming an insulator in the trench; and
removing the mask layer and the pad oxide layer.

7. The method as claimed in claim 6, wherein in the step of forming the liner oxide layer on the surface of the trench and rounding the corner of the trench in the furnace at the same time, the processing gases include hydrogen, oxygen and transdichloroethylene (TLC).

8. The method as claimed in claim 7, wherein the content of TLC is 0.5˜5 wt. %.

9. The method as claimed in claim 7, wherein the temperature used to form the liner oxide layer and round the corner of the trench is 900˜1150° C.

10. The method as claimed in claim 6, wherein in the step of forming the liner oxide layer on the surface of the trench and rounding the corner of the trench in the furnace at the same time, the processing gases include oxygen and transdichloroethylene (TLC).

11. The method as claimed in claim 10, wherein the content of TLC is 0.5˜5 wt. %.

12. The method as claimed in claim 10, wherein the temperature used to form the liner oxide layer and round the corner of the trench is 900˜1150° C.
